(19) United States
(12) Patent Application Publication
(10) Pub. No.: US 2024/0130155 A1
(43) Pub. Date: Apr. 18, 2024

(54) DISPLAY DEVICE

(71) Applicant: Samsung Display Co., LTD., Yongin-si (KR)

(72) Inventors: HEEJIN KIM, Yongin-si (KR); HYERIM KIM, Yongin-si (KR); HANBYUL JANG, Yongin-si (KR); NAMWOO KIM, Yongin-si (KR); Ji Hyun SEO, Yongin-si (KR); Ja Hyun IM, Yongin-si (KR)

(73) Assignee: Samsung Display Co., LTD., Yongin-si (KR)

(21) Appl. No.: 18/354,878

(22) Filed: Jul. 19, 2023

(30) Foreign Application Priority Data
Sep. 16, 2022 (KR) 10-2022-0117449

(51) Int. Cl. H10K 50/18; H10K 50/15; H10K 59/123; H10K 59/13; H10K 59/40; H10K 85/60

(52) U.S. Cl. CPC H10K 50/181; H10K 50/15; H10K 59/123; H10K 59/13; H10K 59/40; H10K 85/615; H10K 2101/40

(57) ABSTRACT

Embodiments provide a display device that includes a substrate, a transistor disposed on the substrate, and a light emitting device that is electrically connected to the transistor. The light emitting device includes a first electrode that is electrically connected to the transistor, a second electrode disposed on the first electrode, a light emitting layer disposed between the first electrode and the second electrode, a hole transport layer disposed between the first electrode and the light emitting layer, and an electron blocking layer disposed between the hole transport layer and the light emitting layer. Mobility of the hole transport layer is equal to or less than about 2.0*10⁻³ cm²/(Vs), and a real part of impedance of the light emitting device is equal to or less than about 100Ω, in a frequency range of about 10⁵ Hz to about 10⁶ Hz.

### CROSS-REFERENCE TO RELATED APPLICATION(S)

This application claims priority to and benefits of Korean Patent Application No. 10-2022-0117449 under 35 U.S.C. § 119, filed on Sep. 16, 2022, in the Korean Intellectual Property Office the entire contents of which are incorporated herein by reference.

### BACKGROUND

### 1. Technical Field

The disclosure relates to a display device.

### 2. Description of the Related Art

A display device is a device for displaying an image, and may include a liquid crystal display (LCD), an organic light emitting diode (OLED) display, or the like. The display device is used in various electronic devices such as a mobile phone, a navigation device, a digital camera, an electronic book, a portable game machine, and various terminals.

An organic light emitting display device includes two electrodes and an organic light emitting layer interposed therebetween, wherein electrons injected from one electrode and holes injected from another electrode are combined in the organic light emitting layer to generate excitons. The generated excitons are changed to a ground state from an excited state, releasing energy to emit light.

Such an organic light emitting display device includes pixels including an organic light emitting diode which is a self-emissive element, and in each pixel, transistors for driving the organic light emitting diode and at least one capacitor may be formed. On/off and emission luminance of the organic light emitting diode of each pixel may be controlled. Although the organic light emitting diode does not have to emit light in an off state, there may be a problem in which a residual light emitted to a rear surface of the display device is generated due to leakage current.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device which may be capable of preventing residual light from being generated in an off state.

A display device according to an embodiment may include: a substrate; a transistor disposed on the substrate; and a light emitting device that is electrically connected to the transistor. The light emitting device may include: a first electrode that is electrically connected to the transistor; a second electrode disposed on the first electrode; a light emitting layer disposed between the first electrode and the second electrode; a hole transport layer disposed between the first electrode and the light emitting layer; and an electron blocking layer disposed between the hole transport layer and the light emitting layer. Mobility of the hole transport layer may be equal to or less than about 2.0*10⁻³ cm²/(Vs), and a real part of impedance of the light emitting device may be equal to or less than about 100Ω, in a frequency range of about 10⁵ Hz to about 10⁶ Hz.

A difference between a highest occupied molecular orbital (HOMO) energy level of the hole transport layer and a HOMO energy level of the electron blocking layer may be equal to or less than about 0.1 eV.

The display device may further include a sensor disposed at a rear surface of the substrate. The sensor may overlap the light emitting device.

The sensor may include an ambient luminance sensor.

The sensor may be operated when the light emitting device in an off state, and the sensor may not be operated when the light emitting device is in an on state.

The sensor may detect incident light outside the display device, and the sensor may adjust a brightness of the display device according to an amount of the incident light.

The display device may further include a support member disposed between the substrate and the sensor. The support member may include a hole overlapping the sensor.

The display device may further include an auxiliary layer disposed on the light emitting device. The auxiliary layer may include at least one of a color filter, a quantum dot color conversion layer, a touch sensor, and a polarization layer.

The hole transport layer may include a compound represented by Chemical Formula 1.

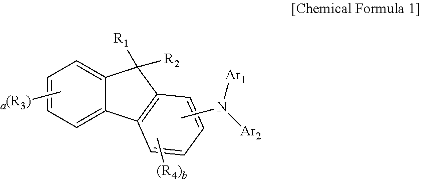

In Chemical Formula 1, R₁ through R₄ may each independently be hydrogen, deuterium, a substituted or unsubstituted C₁-C₃₀ alkyl group, a substituted or unsubstituted C₁-C₃₀ cycloalkyl group, a substituted or unsubstituted C₆-C₃₀ aryl group, or a substituted or unsubstituted C₂-C₃₀ heteroaryl group, or may be bonded to an adjacent group to form a ring; Ar₁ and Ar₂ may each independently be a substituted or unsubstituted C₆-C₃₀ aryl group or a substituted or unsubstituted C₂-C₃₀ heteroaryl group; a may be an integer from 0 to 4; and b may be an integer from 0 to 3.

The electron blocking layer may include the compound represented by Chemical Formula 1.

The electron blocking layer may include a material that is different from a material of the hole transport layer.

The display device may further include an auxiliary electron blocking layer disposed between the electron blocking layer and the light emitting layer. The auxiliary electron blocking layer may include a material that is different from the material of the electron blocking layer.

The auxiliary electron blocking layer may include the compound represented by Chemical Formula 1.

A display device according to another embodiment may include: a display panel; and a sensor disposed at a rear surface of the display panel. The display panel may include: a transistor disposed on a substrate; and a light emitting device that is electrically connected to the transistor. The light emitting device may include: a first electrode that is electrically connected to the transistor; a second electrode disposed on the first electrode; a light emitting layer disposed between the first electrode and the second electrode; a hole transport layer disposed between the first electrode and the light emitting layer; and an electron blocking layer disposed between the hole transport layer and the light emitting layer. A real part of impedance of the light emitting device may be equal to or less than about 100Ω, in a frequency range of about 10⁵ Hz to about 10⁶ Hz.

Mobility of the hole transport layer may be equal to or less than about 2.0*10⁻¹ cm²/(Vs).

A difference between a highest occupied molecular orbital (HOMO) energy level of the hole transport layer and a HOMO energy level of the electron blocking layer may be equal to or less than about 0.1 eV.

The sensor may include an ambient luminance sensor, and the sensor may overlap the light emitting device.

The sensor may be operated when the light emitting device is in an off state, and the sensor may not be operated when the light emitting device is in an on state.

The sensor may detect incident light outside display device, and the sensor may adjust a brightness of the display panel according to an amount of the incident light.

A display device according to another embodiment may include: a display panel including a substrate, a transistor disposed on the substrate, and a light emitting device that is electrically connected to the transistor. The light emitting device may include: a first electrode that is electrically connected to the transistor; a second electrode disposed on the first electrode; a light emitting layer disposed between the first electrode and the second electrode; a hole transport layer disposed between the first electrode and the light emitting layer; and an electron blocking layer disposed between the hole transport layer and the light emitting layer. The hole transport layer and the electron blocking layer may each independently include a compound represented by Chemical Formula 1, and the compound of the electron blocking layer may be different from the compound of the hole transport layer.

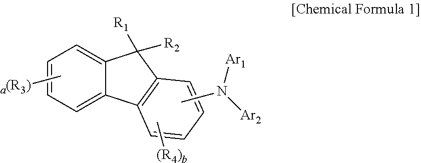

In Chemical Formula 1, R₁ through R₄ may each independently be hydrogen, deuterium, a substituted or unsubstituted C₁-C₃₀ alkyl group, a substituted or unsubstituted C₁-C₃₀ cycloalkyl group, a substituted or unsubstituted C₆-C₃₀ aryl group, or a substituted or unsubstituted C₂-C₃₀ heteroaryl group, or may be bonded to an adjacent group to form a ring; Ar₁ and Ar₂ may each independently be a substituted or unsubstituted C₆-C₃₀ aryl group or a substituted or unsubstituted C₂-C₃₀ heteroaryl group; a may be an integer from 0 to 4; and b may be an integer from 0 to 3.

According to the embodiments, it may possible to prevent the display device from emitting a light in the off state.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of the display device according to an embodiment;

FIG. 3 is a schematic cross-sectional view illustrating the display device according to an embodiment;

FIG. 4 is a schematic cross-sectional view illustrating a stacked structure of a light emitting device of the display device according to an embodiment;

FIG. 5 is a schematic cross-sectional view illustrating a stacked structure of the light emitting device of the display device according to an embodiment;

FIG. 6 is a schematic cross-sectional view illustrating an optical path when the light emitting device of the display device is in an on state according to an embodiment;

FIG. 7 is a schematic cross-sectional view illustrating an optical path when the light emitting device of the display device is in an off state according to an embodiment;

FIG. 8 is a schematic cross-sectional view illustrating an optical path when a light emitting device of a display device according to a reference example is in an off state according to an embodiment;

FIG. 9 is a view illustrating a front surface of the display device when the light emitting device of the display device according to the reference example is in the off state according to an embodiment;

FIG. 10 is a view illustrating a rear surface of the display device when the light emitting device of the display device according to the reference example is in the off state according to an embodiment;

FIG. 11 is a schematic view illustrating an energy level diagram of the light emitting device of the display device according to an embodiment;

FIG. 12 is a schematic diagram of an equivalent circuit of the light emitting device of the display device according to an embodiment;

FIG. 13 is a graph illustrating an imaginary part of a modulus of the light emitting device of the display device according to the reference example according to an embodiment;

FIG. 14 is a graph illustrating a real part of impedance of the light emitting device of the display device according to the reference example according to an embodiment;

FIG. 15 is a graph illustrating an imaginary part of a modulus of the light emitting device of the display device according to the reference example according to an embodiment;

FIG. 16 is a graph illustrating a real part of impedance of the light emitting device of the display device according to the reference example according to an embodiment;

FIG. 17 is a graph illustrating an imaginary part of a modulus of the display device according to the reference example or the light emitting device of the display device according to an embodiment;

FIG. 18 is a graph illustrating a real part of impedance of the display device according to the reference example or the light emitting device according to an embodiment;

FIG. 19 is a graph illustrating a real part of impedance in a frequency range of about 10⁵ Hz to about 10⁶ Hz according to an embodiment; and

FIG. 20 is a graph illustrating a ratio of amounts of light emitted from a rear surface of the display device according to the reference example and a ratio of amounts of light emitted from a rear surface of the display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

In the specification, the word “on” or “above” means positioned or disposed on or below the object portion, and does not necessarily mean positioned or disposed on the upper side of the object portion based on a gravitational direction.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the phrase “in a plan view” or “on a plane” means viewing a target portion from the top, and the phrase “in a cross-sectional view” or “on a cross-section” means viewing a cross-section formed by vertically cutting a target portion from the side.

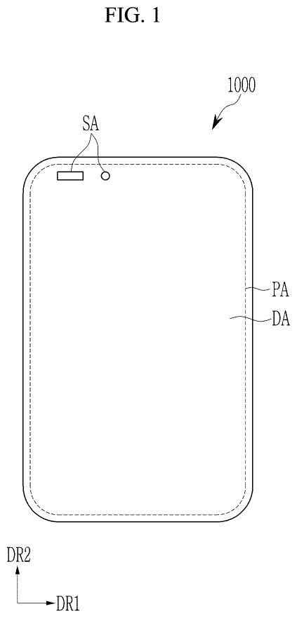

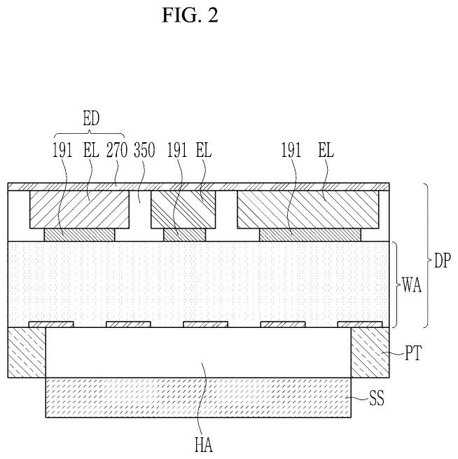

Hereinafter, a display device according to an embodiment will be described with reference to FIGS. 1 and 2.

FIG. 1 is a schematic plan view of a display device according to an embodiment. FIG. 2 is a schematic cross-sectional view of the display device according to the embodiment. FIG. 1 shows an overall shape of the display device according to the embodiment, and FIG. 2 shows a sensor area that is a partial area of the display device according to the embodiment.

The display device 1000 according to the embodiment may be a device that displays a moving image or a still image, and may be used for a display screen for a portable electronic device such as a mobile phone, a smart phone, a tablet personal computer (PC), a mobile communication terminal, an electronic note, an electronic book, a portable multimedia player (PMP), a navigation device, an ultra mobile PC (UMPC), or the like, and various products such as a television, a laptop computer, a monitor, a billboard, an Internet of things (IOT), and the like. The display device 1000 according to the embodiment may be used in a wearable device such as a smart watch, a watch phone, a glass-type display, and a head mounted display (HMD). The display device 1000 according to the embodiment may be used as a center information display (CID) disposed at a dashboard and a center fascia of a vehicle, a room mirror display in place of a side mirror of a vehicle, an entertainment unit for a rear seat of a vehicle, or a head-up display.

The display device 1000 according to the embodiment may include a display panel DP displaying an image and a sensor SS positioned at a rear surface of the display panel DP. For example, a screen may be displayed by light emitted from a front surface of the display panel DP, and the sensor SS may be positioned at a rear surface of the display panel DP opposite to a direction in which the screen is displayed.

The display panel DP may include a display area DA and a peripheral area PA positioned adjacent to the display area DA.

The display area DA is an area for displaying a screen and may have a substantially rectangular shape. For example, the display area DA may include a rectangular shape including two sides extending in a first direction DR1 and two sides extending in a second direction DR2, and a corner portion of the display area DA may be chamfered in a round shape. However, this is only an example, and a shape of the display area DA may be changed according to a use of the display device according to an embodiment.

Light emitting devices ED may be disposed at the display area DA in a form (e.g., a predetermined or a selectable form). For example, the light emitting devices ED may be disposed in a row direction and a column direction. However, this is only an example, and an arrangement form of the light emitting devices ED may be variously changed. Each of the light emitting devices ED may include a first electrode 191, a second electrode 270, and an intermediate layer EL positioned therebetween. The first electrode 191 may be an anode electrode, the second electrode 270 may be a cathode electrode, and the intermediate layer EL may include an organic material or an inorganic material capable of emitting light. A partition wall 350 may be positioned between the light emitting devices ED. For example, the light emitting devices ED may be divided by the partition wall 350. The second electrode 270 may not be divided and may be formed to be entirely connected.

Each of the light emitting devices ED may receive a signal (e.g., a predetermined or a selectable signal) through signal lines. The signal lines and the light emitting device ED may be connected through a transistor. For example, the transistor and the signal lines connected to the light emitting device ED may be positioned at the display area DA, and for convenience, a portion where the transistor and the signal lines are positioned is indicated as a wiring area WA. The signal line may include a scan line, a data line, a driving voltage line, an initialization voltage line, a common voltage line, or the like. The signal line may extend in the first direction DR1 or the second direction DR2 to be connected to the light emitting devices ED. At least some of the transistor and the signal lines positioned at the wiring area WA may be made of an opaque conductive material. Most of light emitted from the light emitting device ED may exit to a front surface of the display device, and a part of the light may be transmitted to a rear surface of the display device (or the display panel DP). A part of the light transmitted to the rear surface of the display panel DP may be reflected by the opaque conductive material positioned at the wiring area WA, and the other part of the light may pass through the wiring area WA to reach the sensor SS.

A touch sensor for detecting a contact and/or non-contact touch of a user may be further positioned at the display area DA.

The peripheral area PA may be positioned outside the display area DA and may have a shape surrounding the display area DA. A drive device (or a driving unit) such as a driving circuit chip, a flexible printed circuit, a scan driving device, or the like for generating and transmitting a signal driving the display device according to the embodiment may be positioned at the peripheral area PA. The driving circuit chip may be connected to the light emitting device ED positioned at the display area DA through a wire, and may transmit various signals such as a data signal and the like. The flexible printed circuit 30 may be made of a flexible material, and a circuit for controlling driving of the display device according to the embodiment may be designed in the flexible printed circuit. The scan driving device may be positioned adjacent to a left edge and/or a right edge of the display area DA, may be connected to the light emitting device ED through a scan line, and may transmit a scan signal. Each of the light emitting devices ED may receive the data signal at timing (e.g., a predetermined or a selectable timing) according to the scan signal. A signal line for transmitting various control signals, a driving voltage, a common voltage, or the like may be positioned at the peripheral area PA.

The display panel DP may further include a sensor area SA, and the sensor area SA may be positioned within the display area DA. The sensor SS may overlap the sensor area SA of the display panel DP, and may be electrically connected to the display panel DP to transmit and receive a signal (e.g., a predetermined or a selectable signal). The sensor SS may detect light, heat, or the like entering from the outside. For example, the sensor SS may include an ambient luminance sensor (ALS). The ambient luminance sensor (ALS) may detect light coming from the outside to determine brightness of a surrounding environment in which the user uses the display device and to adjust brightness of the display panel DP according to an incident amount of external light. In a dark place, after the ambient luminance sensor (ALS) recognizes a state in which the external light is low, the ALS may transmit a signal (e.g., a predetermined or a selectable signal) to the display panel DP to lower the brightness of the display panel DP. In a bright place, the ambient luminance sensor (ALS) may recognize a state in which the external light is high, and the ALS may increase the brightness of the display panel DP by transmitting a signal (e.g., a predetermined or a selectable signal) to the display panel DP. The light emitting device ED may also be positioned in the sensor area SA. Accordingly, the light emitting device ED may overlap the sensor SS.

To the ambient luminance sensor (ALS), various electronic modules may be positioned at the sensor area SA. For example, an infrared detection sensor, a camera, a speaker, or the like may be positioned in the sensor area SA. One or more electronic modules may be positioned at the sensor area SA.

A support member PT may be positioned between the display panel DP and the sensor area SA. The support member PT may be positioned on the rear surface of the display panel DP and may have a planar shape similar to that of the display panel DP. The support member PT may be made of a hard material to serve to support the display panel DP. For example, the support member PT may be formed of a metal material or a non-metal material such as a carbon fiber reinforced plastic (CFRP) or the like. A hole HA overlapping the sensor area SA may be formed at the support member PT, and the sensor SS may overlap the hole HA. The sensor SS may detect light incident from the outside through the hole HA formed in the support member PT. External light may be partially lost while passing through the light emitting device ED and the wiring area WA, and the remaining light of the external light may pass through the hole HA of the support member PT to be transmitted to the sensor SS. In FIG. 2, the sensor SS is illustrated as being positioned below the support member PT, but is not limited thereto, and the sensor SS may be positioned inside the hole HA of the support member PT.

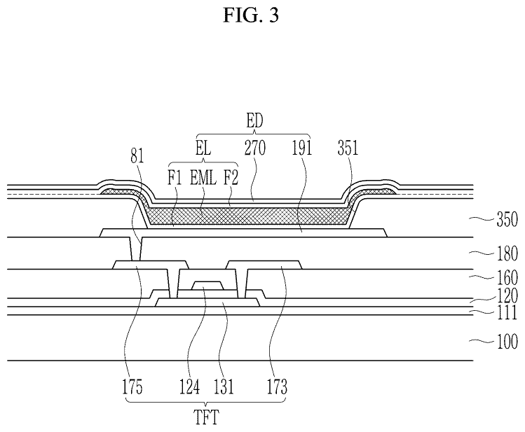

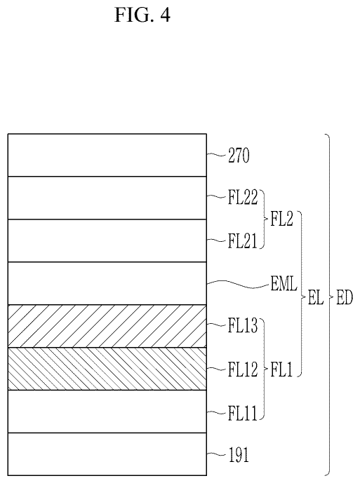

Hereinafter, one pixel of the display device according to an embodiment will be described with reference to FIGS. 3 and 4.

FIG. 3 is a schematic cross-sectional view illustrating the display device according to the embodiment. FIG. 4 is a schematic cross-sectional view illustrating a stacked structure of the light emitting device of the display device according to the embodiment. FIG. 3 illustrates a transistor and a light emitting device included in one pixel of the display device according to the embodiment.

As shown in FIG. 3, the display device according to the embodiment may include a substrate 100, a transistor TFT that is positioned on the substrate 100 and includes a semiconductor 131, a gate electrode 124, a source electrode 173, and a drain electrode 175, a gate insulating film 120, a first interlayer insulating film 160, a second interlayer insulating film 180, a first electrode 191, the intermediate layer EL, the partition wall 350, and a second electrode 270. According to an embodiment, the first electrode 191, the intermediate layer EL, and the second electrode 270 may form the light emitting device ED, and the light emitting device ED may be connected to the transistor TFT.

The substrate 100 may include a material having a rigid property such as glass or the like or a flexible material that is bent such as plastic or the like. For example, the substrate 100 may include a material such as polystyrene, polyvinyl alcohol, polymethylmethacrylate, polyethersulfone, polyacrylate, polyetherimide, polyethylene naphthalate, polyethylene terephthalate, polyphenylene sulfide, polyarylate, polyimide, polycarbonate, cellulose triacetate, cellulose acetate propionate, or the like. The substrate 100 may be a single layer or a multilayer. The substrate 100 may be alternately stacked with at least one base layer including sequentially stacked polymer resins, and at least one inorganic layer.

A buffer layer 111 for leveling a surface of the substrate 100 and blocking penetration of impurities may be further positioned on the substrate 100. The buffer layer 111 may include an inorganic material, and may include an inorganic insulating material such as silicon nitride (SiNₓ), a silicon oxide (SiOₓ), a silicon oxynitride (SiOₓN_{y}), or the like. The buffer layer 111 may have a single layer or a multilayer structure of the material. A barrier layer (not shown) may be further positioned on the substrate 100. The barrier layer may be positioned between the substrate 100 and the buffer layer 111. The barrier layer may include an inorganic insulating material such as a silicon nitride (SiNₓ), a silicon oxide (SiOₓ), a silicon oxynitride (SiOₓN_{y}), or the like. The barrier layer may have a single layer or a multilayer structure of the material.

The semiconductor 131 may be positioned on the substrate 100. The semiconductor 131 may include any one of amorphous silicon, polycrystalline silicon, and an oxide semiconductor. For example, the semiconductor 131 may include low-temperature polysilicon (LTPS) or an oxide semiconductor including at least one of zinc (Zn), indium (In), gallium (Ga), tin (Sn), and any mixture thereof. For example, the semiconductor 131 may include Indium-Gallium-Zinc Oxide (IGZO). The semiconductor 131 may include a channel region, a source region, and a drain region that may be divided according to whether the semiconductor 131 is doped with impurities. The source region or the drain region may have a conductive property corresponding to a conductor.

The gate insulating film 120 may cover the semiconductor 131 and the buffer layer 111. The gate insulating film 120 may include an inorganic insulating material such as a silicon nitride (SiNₓ), a silicon oxide (SiOₓ), a silicon oxynitride (SiOₓN_{y}), or the like. The gate insulating film 120 may have a single layer or a multilayer structure of the material.

The gate electrode 124 may be positioned on the gate insulating film 120. The gate electrode 124 may include a metal such as copper (Cu), molybdenum (Mo), aluminum (Al), silver (Ag), chromium (Cr), tantalum (Ta), titanium (Ti), or the like, or a metal alloy. The gate electrode 124 may be formed of a single layer or multiple layers. The gate electrode 124 may overlap the semiconductor 131.

When the gate electrode 124 is formed, a doping process or plasma treatment may be performed. A portion of the semiconductor 131 covered by the gate electrode 124 may not be doped or plasma-treated, and a portion of the semiconductor 131 not covered by the gate electrode 124 may be doped or plasma-treated to have a same characteristic as a conductor. A region of the semiconductor 131 that overlaps the gate electrode 124 in a plan view may be the channel region.

The first interlayer insulating film 160 may cover the gate electrode 124 and the gate insulating film 120. The first interlayer insulating film 160 may include an inorganic insulating material such as a silicon nitride (SiNₓ), a silicon oxide (SiOₓ), a silicon oxynitride (SiOₓN_{y}), or the like. The first interlayer insulating film 160 may have a single layer or a multilayer structure of the material.

The source electrode 173 and the drain electrode 175 may be positioned on the first interlayer insulating film 160. The source electrode 173 and the drain electrode 175 may be respectively connected to the source region and the drain region of the semiconductor 131 through an opening formed in the first interlayer insulating film 160 and an opening formed in the gate insulating film 120. Accordingly, the semiconductor 131, the gate electrode 124, the source electrode 173, and the drain electrode 175 may form one transistor TFT. According to an embodiment, the transistor TFT may include only the source region and the drain region of the semiconductor 131 instead of the source electrode 173 and the drain electrode 175.

The source electrode 173 or the drain electrode 175 may include a metal such as aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), or the like, or a metal alloy. The source electrode 173 or the drain electrode 175 may be formed of a single layer or multiple layers. For example, the source electrode 173 and the drain electrode 175 may be configured as a triple layer including an upper layer, an intermediate layer, and a lower layer. The upper layer or the lower layer may include titanium (Ti), and the intermediate layer may include aluminum (Al).

The second interlayer insulating film 180 may be positioned on the source electrode 173 and the drain electrode 175. The second interlayer insulating film 180 covers the source electrode 173, the drain electrode 175, and the first interlayer insulating film 160. The second interlayer insulating film 180 may be for planarizing a surface of the transistor TFT formed on the substrate 100, and may be an organic insulating film. The second interlayer insulating film 180 may include at least one material selected from the group consisting of polyimide, polyamide, acrylic resin, benzocyclobutene, and phenol resin.

The first electrode 191 may be positioned on the second interlayer insulating film 180. The first electrode 191 may also be referred to as an anode electrode, and may be formed of a single layer including a transparent conductive oxide film or a metal material, or a multilayer including the single layer. The transparent conductive oxide film may include indium tin oxide (ITO), poly-ITO, indium zinc oxide (IZO), indium gallium zinc oxide (IGZO), indium tin zinc oxide (ITZO), and the like. The metal material may include silver (Ag), molybdenum (Mo), copper (Cu), gold (Au), aluminum (Al), and the like. For example, the first electrode 191 may have a triple layer structure such as ITO-silver (Ag)-ITO.

The second interlayer insulating film 180 may include a via hole 81 exposing the drain electrode 175. The drain electrode 175 and the first electrode 191 may be physically and electrically connected to each other through the via hole 81 of the second interlayer insulating film 180. Accordingly, the first electrode 191 may receive an output current to be transferred from the drain electrode 175 to the intermediate layer EL.

The partition wall 350 may be positioned on the first electrode 191 and the second interlayer insulating film 180. The partition wall 350 is also referred to as a pixel defining layer (PDL), and may include a pixel opening 351 overlapping at least a portion of the first electrode 191. The pixel opening 351 may correspond to an emission area of the light emitting device ED. The pixel opening 351 may overlap a central portion of the first electrode 191 and may not overlap an edge portion of the first electrode 191. Accordingly, a size of the pixel opening 351 may be smaller than a size of the first electrode 191. The partition wall 350 may be an organic insulating film including at least one material selected from the group consisting of polyimide, polyamide, acrylic resin, benzocyclobutene, and phenol resin. According to an embodiment, the partition wall 350 may include a light blocking material. The light blocking material may include carbon black, carbon nanotubes, a resin or a paste including a black dye, metal particles, e.g., nickel, aluminum, molybdenum, and an alloy thereof, metal oxide particles (e.g., chromium oxide), metal nitride particles (e.g., chromium nitride), or the like. When the partition wall 350 includes the light blocking material, reflection of external light by metal structures disposed under the partition wall 350 may be reduced.

The intermediate layer EL may be positioned on the first electrode 191 and the partition wall 350. The intermediate layer EL may include a light emitting layer EML and functional layers FL1 and FL2.

The light emitting layer EML may be a layer in which electro-optical conversion is performed through a combination of an electron and a hole, and may be positioned between the first electrode 191 and the second electrode 270. The light emitting layer EML may include an organic material and/or an inorganic material emitting light of a color (e.g., a predetermined or a selectable color). For example, the light emitting layer EML may include a low-molecular organic material or a high-molecular organic material that emits light such as red light, green light, blue light, or the like. The display device according to the embodiment may include pixels. Some of the pixels may be red pixels displaying red, others of the pixels may be green pixels displaying green, and the remaining pixels may be blue pixels displaying blue. The light emitting layer EML including an organic material emitting red light may be positioned in the red pixels, the light emitting layer EML including an organic material emitting green light may be positioned in the green pixels, and the light emitting layer EML including an organic material emitting blue light may be positioned in the blue pixels. The light emitting layer EML may be positioned in the pixel opening 351 of the partition wall 350, and may overlap the first electrode 191. In an embodiment, one portion of the light emitting layer EML may also be positioned on a side surface and an upper surface of the partition wall 350. In an embodiment, the light emitting layer EML may be positioned on the upper surface of the partition wall 350 adjacent to the pixel opening 351

As shown in FIG. 4, the functional layers FL1 and FL2 may include at least one of a hole injection layer FL11, a hole transport layer FL12, an electron blocking layer FL13, a hole blocking layer FL21, and an electron transport layer FL22. The functional layer FL may be divided into a first functional layer FL1 positioned between the first electrode 191 and the light emitting layer EML, and a second functional layer FL2 positioned between the light emitting layer EML and the second electrode 270. The first functional layer FL1 may include the hole injection layer FL11, the hole transport layer FL12, and/or the electron blocking layer FL13. The hole transport layer FL12 may be positioned between the first electrode 191 and the light emitting layer EML, the electron blocking layer FL13 may be positioned between the hole transport layer FL12 and the light emitting layer EML, and the hole injection layer FL11 may be positioned between the first electrode 191 and the hole transport layer FL12. However, this is only an example, and some of three layers constituting the first functional layer FL1 may be omitted, and another layer may be further included in the first functional layer FL1. The second functional layer FL2 may include the hole blocking layer FL21 and/or the electron transport layer FL22. The hole blocking layer FL21 may be positioned between the light emitting layer EML and the second electrode 270, and the electron transport layer FL22 may be positioned between the hole blocking layer FL21 and the second electrode 270. However, this is only an example, and some of two layers constituting the second functional layer FL2 may be omitted, and another layer may be further included in the second functional layer FL2.

Mobility (or hole mobility) of the hole transport layer FL12 in the first functional layer FL1 may be equal to or less than about 2.0*10⁻³ cm²/(Vs). In an embodiment, a difference between a highest occupied molecular orbital (HOMO) energy level of the hole transport layer FL12 and a HOMO energy level of the electron blocking layer FL13 may be equal to or less than about 0.1 eV. In an embodiment, a real part of impedance of the light emitting device ED may be equal to or less than about 100Ω, in a frequency range of about 10⁵ Hz to about 10⁶ Hz. Each of these numerical ranges will be described again later.

A material of the hole transport layer FL12 and a material of the electron blocking layer FL13 that satisfy the numerical range may be selected and used. For example, the hole transport layer FL12 may include a compound (e.g., an amine compound having a substituted fluorene moiety) represented by Chemical Formula 1. The electron blocking layer FL13 may include a compound that is represented by Chemical Formula 1 and is different from the compound of the hole transport layer FL12.

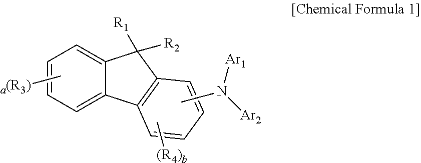

In Chemical Formula 1, R₁ through R₄ may each independently be hydrogen, deuterium, a substituted or unsubstituted C₁-C₃₀ alkyl group, a substituted or unsubstituted C₁-C₃₀ cycloalkyl group, a substituted or unsubstituted C₆-C₃₀ aryl group, or a substituted or unsubstituted C₂-C₃₀ heteroaryl group, or may be bonded to an adjacent group to form a ring, Ar₁ and Ar₂ may each independently be a substituted or unsubstituted C₆-C₃₀ aryl group or a substituted or unsubstituted C₂-C₃₀ heteroaryl group, a may be an integer from 0 to 4, and b may be an integer from 0 to 3.

In an embodiment, the hole transport layer FL1 2 may include at least one of the following Compounds HT1 through HT12.

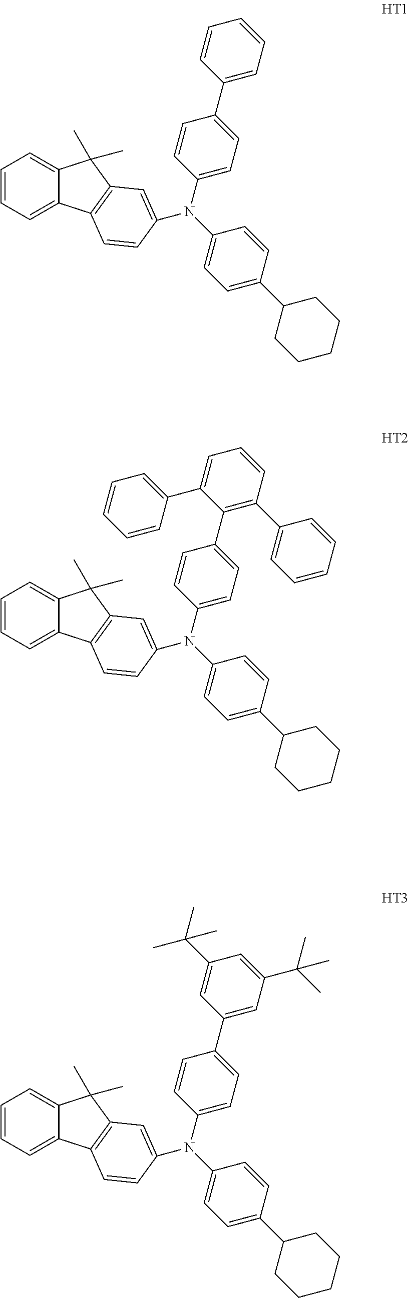 [SMILES: CC1(C)c2ccccc2-c2ccc(N(c3ccc(-c4ccccc4)cc3)c3ccc(C4CCCCC4)cc3)cc21 ; CC1(C)c2ccccc2-c2ccc(N(c3ccc(-c4c(-c5ccccc5)cccc4-c4ccccc4)cc3)c3ccc(C4CCCCC4)cc3)cc21 ; CC(C)(C)c1cc(-c2ccc(N(c3ccc(C4CCCCC4)cc3)c3ccc4c(c3)C(C)(C)c3ccccc3-4)cc2)cc(C(C)(C)C)c1]

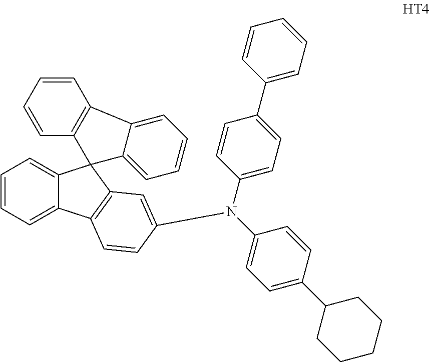 [SMILES: c1ccc(-c2ccc(N(c3ccc(C4CCCCC4)cc3)c3ccc4c(c3)C3(c5ccccc5-c5ccccc53)c3ccccc3-4)cc2)cc1]

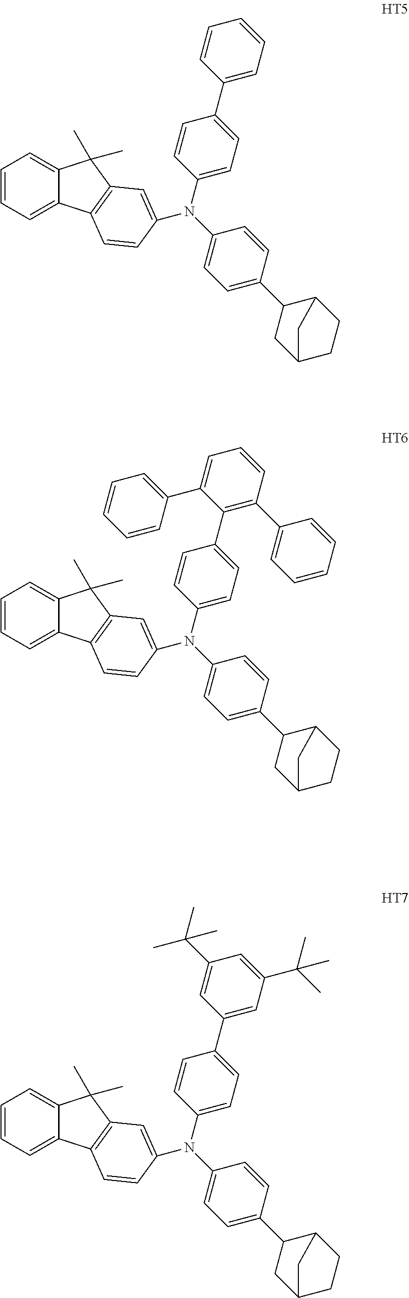 [SMILES: CC1(C)c2ccccc2-c2ccc(N(c3ccc(-c4ccccc4)cc3)c3ccc(C4CC5CCC4C5)cc3)cc21 ; CC1(C)c2ccccc2-c2ccc(N(c3ccc(-c4c(-c5ccccc5)cccc4-c4ccccc4)cc3)c3ccc(C4CC5CCC4C5)cc3)cc21 ; CC(C)(C)c1cc(-c2ccc(N(c3ccc(C4CC5CCC4C5)cc3)c3ccc4c(c3)C(C)(C)c3ccccc3-4)cc2)cc(C(C)(C)C)c1]

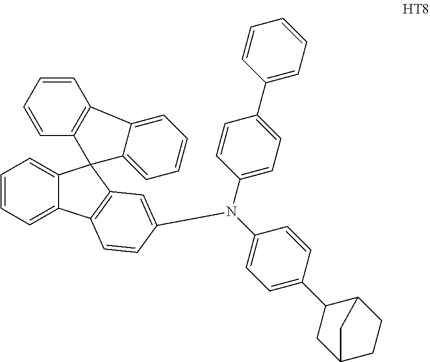 [SMILES: c1ccc(-c2ccc(N(c3ccc(C4CC5CCC4C5)cc3)c3ccc4c(c3)C3(c5ccccc5-c5ccccc53)c3ccccc3-4)cc2)cc1]

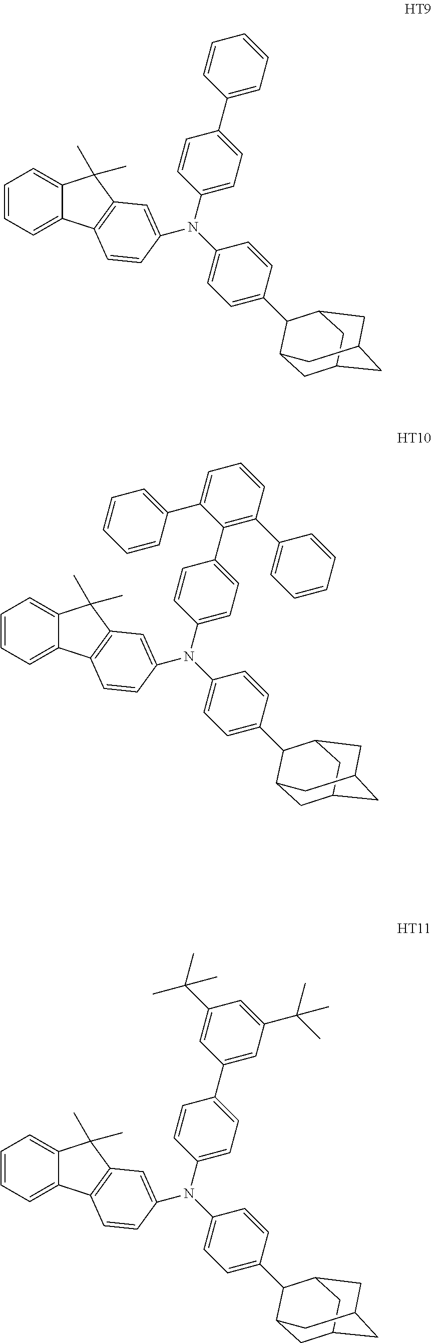 [SMILES: CC1(C)c2ccccc2-c2ccc(N(c3ccc(-c4ccccc4)cc3)c3ccc(C4C5CC6CC(C5)CC4C6)cc3)cc21 ; CC1(C)c2ccccc2-c2ccc(N(c3ccc(-c4c(-c5ccccc5)cccc4-c4ccccc4)cc3)c3ccc(C4C5CC6CC(C5)CC4C6)cc3)cc21 ; CC(C)(C)c1cc(-c2ccc(N(c3ccc(C4C5CC6CC(C5)CC4C6)cc3)c3ccc4c(c3)C(C)(C)c3ccccc3-4)cc2)cc(C(C)(C)C)c1]

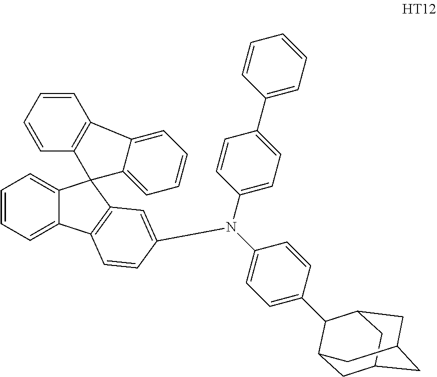 [SMILES: c1ccc(-c2ccc(N(c3ccc(C4C5CC6CC(C5)CC4C6)cc3)c3ccc4c(c3)C3(c5ccccc5-c5ccccc53)c3ccccc3-4)cc2)cc1]

In an embodiment, the electron blocking layer FL13 may include any one of the following Compounds HT13 through HT24.

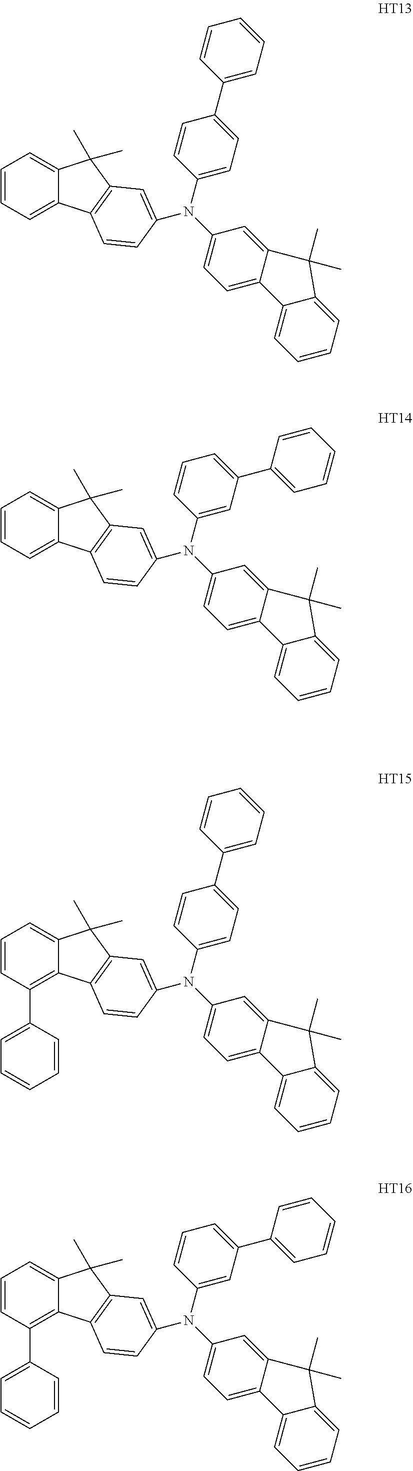 [SMILES: CC1(C)c2ccccc2-c2ccc(N(c3ccc(-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc4c(c3)C(C)(C)c3ccccc3-4)cc21 ; CC1(C)c2ccccc2-c2ccc(N(c3ccc(-c4ccccc4)cc3)c3ccc4c(c3)C(C)(C)c3cccc(-c5ccccc5)c3-4)cc21 ; CC1(C)c2ccccc2-c2ccc(N(c3cccc(-c4ccccc4)c3)c3ccc4c(c3)C(C)(C)c3cccc(-c5ccccc5)c3-4)cc21]

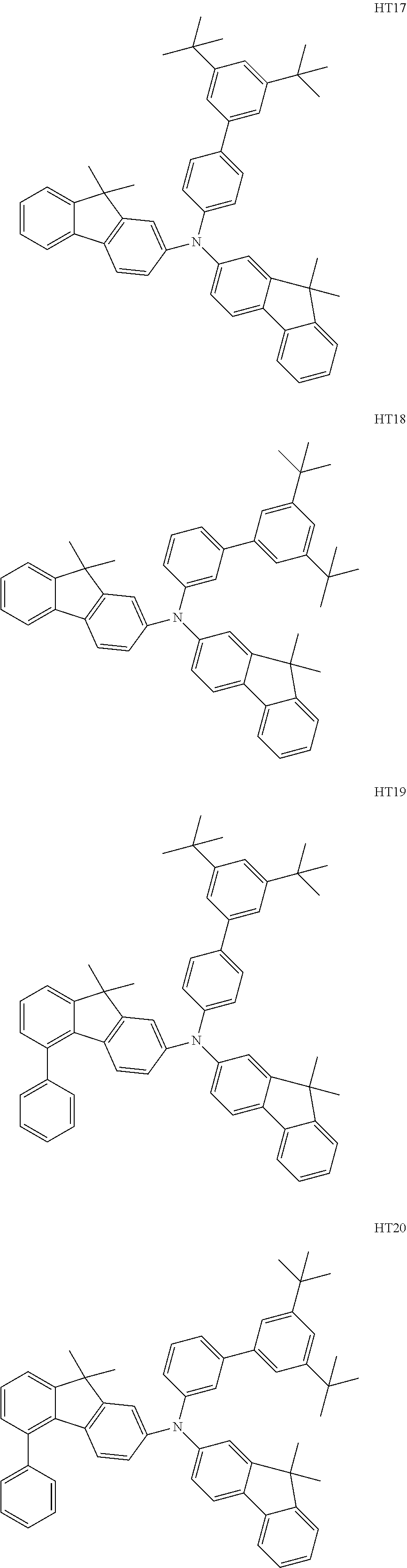 [SMILES: CC(C)(C)c1cc(-c2ccc(N(c3ccc4c(c3)C(C)(C)c3ccccc3-4)c3ccc4c(c3)C(C)(C)c3ccccc3-4)cc2)cc(C(C)(C)C)c1 ; CC(C)(C)c1cc(-c2cccc(N(c3ccc4c(c3)C(C)(C)c3ccccc3-4)c3ccc4c(c3)C(C)(C)c3ccccc3-4)c2)cc(C(C)(C)C)c1 ; CC(C)(C)c1cc(-c2ccc(N(c3ccc4c(c3)C(C)(C)c3ccccc3-4)c3ccc4c(c3)C(C)(C)c3cccc(-c5ccccc5)c3-4)cc2)cc(C(C)(C)C)c1 ; CC(C)(C)c1cc(-c2cccc(N(c3ccc4c(c3)C(C)(C)c3ccccc3-4)c3ccc4c(c3)C(C)(C)c3cccc(-c5ccccc5)c3-4)c2)cc(C(C)(C)C)c1]

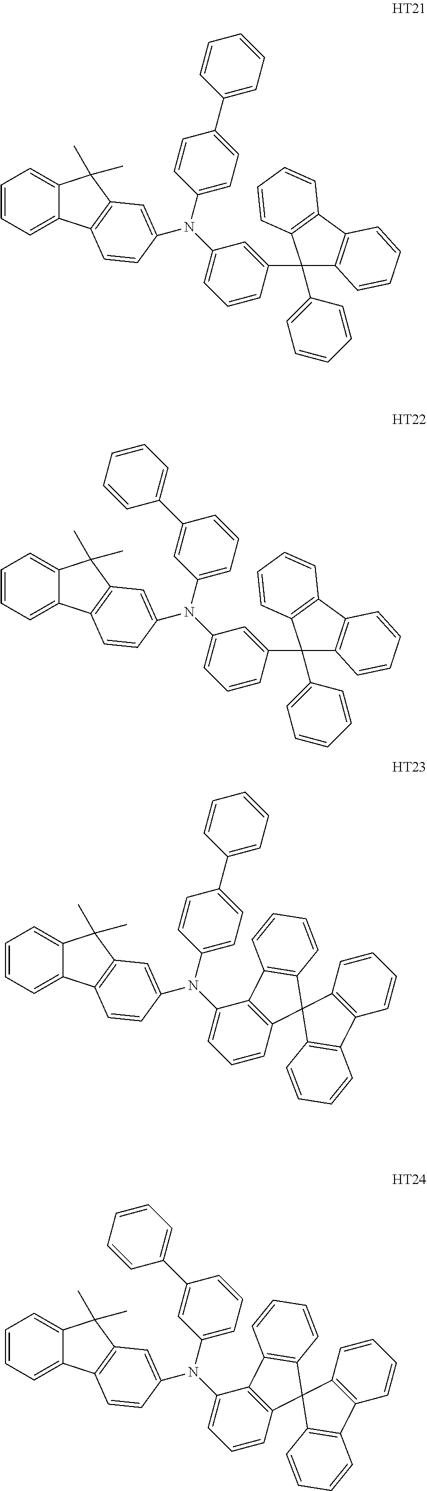 [SMILES: CC1(C)c2ccccc2-c2ccc(N(c3ccc(-c4ccccc4)cc3)c3cccc(C4(c5ccccc5)c5ccccc5-c5ccccc54)c3)cc21 ; CC1(C)c2ccccc2-c2ccc(N(c3cccc(-c4ccccc4)c3)c3cccc(C4(c5ccccc5)c5ccccc5-c5ccccc54)c3)cc21 ; CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3cccc(-c4ccccc4)c3)c3cccc4c3-c3ccccc3C43c4ccccc4-c4ccccc43)cc21]

The hole injection layer FL11 may include a same material as the hole transport layer FL12. The hole injection layer FL11 may be formed by performing p-type doping on the same material as the hole transport layer FL12.

The first functional layer FL1 and the second functional layer FL2 may be positioned over the entire display area DA. The first functional layer FL1 and the second functional layer FL2 may be positioned not only inside the pixel opening 351 of the partition wall 350 but also outside the pixel opening 351. For example, the first functional layer FL1 and the second functional layer FL2 may be formed to entirely cover a side surface and an upper surface of the partition wall 350. The first functional layer FL1 and the second functional layer FL2 may be formed to be connected to pixels. The light emitting layer EML may be positioned between the first functional layer FL1 and the second functional layer FL2 in the pixel opening 351. In a portion where the light emitting layer EML is not formed, the second functional layer FL2 may be positioned on (e.g., directly on) the first functional layer FL1.

The second electrode 270 may be positioned on the intermediate layer EL. The second electrode 270 may also be referred to as a cathode electrode, and may be formed of a transparent conductive layer including indium tin oxide (ITO), indium zinc oxide (IZO), indium gallium zinc oxide (IGZO), indium tin zinc oxide (ITZO), or the like. The second electrode 270 may have a translucent characteristic, and the second electrode 270 may form a microcavity together with the first electrode 191. According to an embodiment, when there is a microcavity structure, light of a specific wavelength may be emitted upward by spacing and a characteristic between both electrodes, and as a result, red, green, or blue may be displayed.

A capping layer (not shown) may be positioned on the second electrode 270. The capping layer may improve light efficiency by adjusting a refractive index. An encapsulation layer (not shown) may be positioned on the capping layer. The encapsulation layer may prevent penetration of moisture or oxygen from the outside by encapsulating the light emitting device ED. The encapsulation layer may be a thin film encapsulation layer including at least one inorganic layer and at least one organic layer. The encapsulation layer may be provided in a form of a substrate to be bonded to the substrate 100. A sealing member may be positioned between the substrate 100 and the encapsulation layer. A touch sensor layer (not shown) may be positioned on the encapsulation layer, and an anti-reflection layer (not shown) for reducing reflection of external light may be positioned on the touch sensor layer. A color filter, a quantum dot color conversion layer, a polarization layer, or the like may be positioned above or on the light emitting device ED.

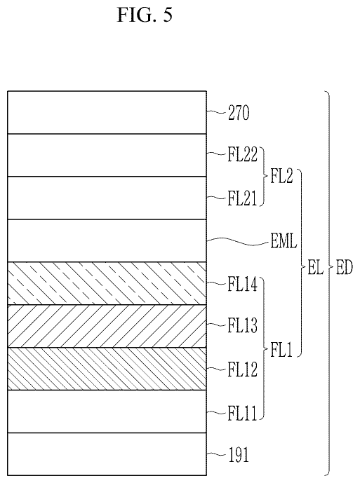

The display device according to an embodiment will be described below with reference to FIG. 5.

According to an embodiment, the display device shown in FIG. 5 may have substantially the same parts as the display device shown in FIGS. 1 to 4, and thus descriptions of the same parts will be omitted. An embodiment associated with FIG. 5 may be different from the previous embodiment in that it further includes an auxiliary electron blocking layer that will be further described below.

FIG. 5 is a schematic cross-sectional view illustrating a stacked structure of the light emitting device of the display device according to the embodiment.

As shown in FIG. 5, the display device according to the embodiment includes a light emitting device ED, and the light emitting device ED may include the first electrode 191, the second electrode 270, and the intermediate layer EL positioned between the first electrode 191 and the second electrode 270. As in the previous embodiment, the intermediate layer EL may include the light emitting layer EML positioned between the first electrode 191 and the second electrode 270, the hole transport layer FL12 positioned between the first electrode 191 and the light emitting layer EML, and the electron blocking layer FL13 positioned between the hole transport layer FL12 and the light emitting layer EML. The intermediate layer EL may further include the hole injection layer FL11, the hole blocking layer FL21, the electron transport layer FL22, and the like.

In the embodiment, the light emitting device ED may further include an auxiliary electron blocking layer FL14. The auxiliary electron blocking layer FL14 may be included in the first functional layer FL1 and may be positioned between the electron blocking layer FL13 and the light emitting layer EML. A thickness of the auxiliary electron blocking layer FL14 may be thinner than a thickness of the electron blocking layer FL13. For example, the electron blocking layer FL13 may have a thickness of about 250 nm, and the auxiliary electron blocking layer FL14 may have a thickness of about 50 nm. However, this is only an example, and the thickness of the electron blocking layer FL13 and the thickness of the auxiliary electron blocking layer FL14 are not limited to those examples.

The auxiliary electron blocking layer FL14 may include a compound represented by Chemical Formula 1, and may include a different material from that of the electron blocking layer FL13. For example, the auxiliary electron blocking layer FL14 may include a compound represented by Chemical Formula 4. The compound represented by Chemical Formula 4 may have a HOMO energy level of about −5.28 eV, a dipole moment of the compound may be about 0.98, and mobility of the compound may be about 1.26*10⁻³ cm²/(Vs).

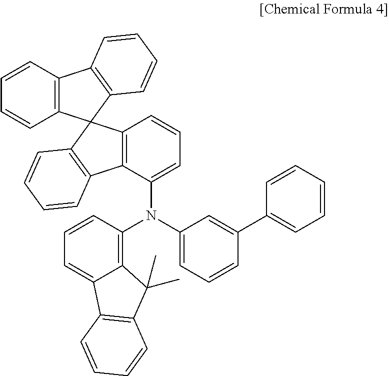 [SMILES: CC1(C)c2ccccc2-c2cccc(N(c3cccc(-c4ccccc4)c3)c3cccc4c3-c3ccccc3C43c4ccccc4-c4ccccc43)c21]

When the electron blocking layer FL13 includes a compound represented by HT20, the auxiliary electron blocking layer FL14 may include a compound represented by HT21.

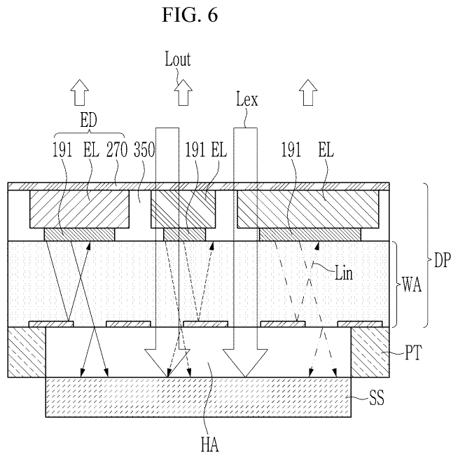

Hereinafter, light emitted from the display device according to the embodiment and incident light in the display device from outside will be described with reference to FIGS. 6 to 10.

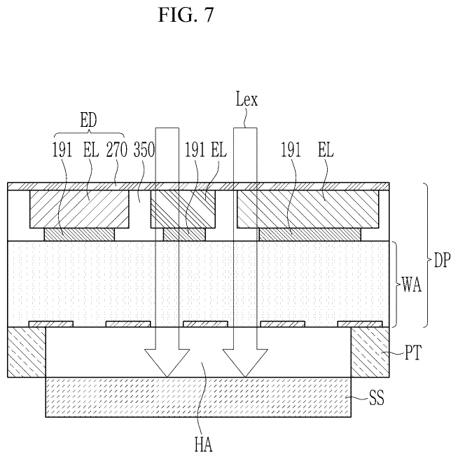

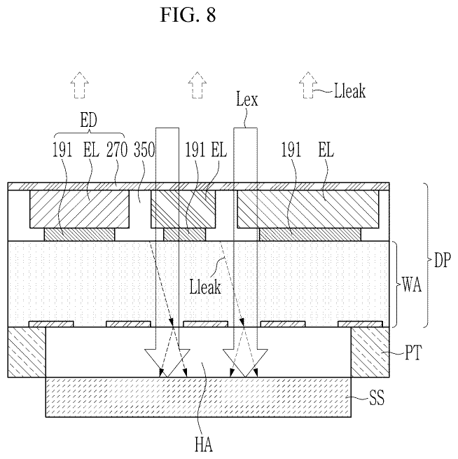

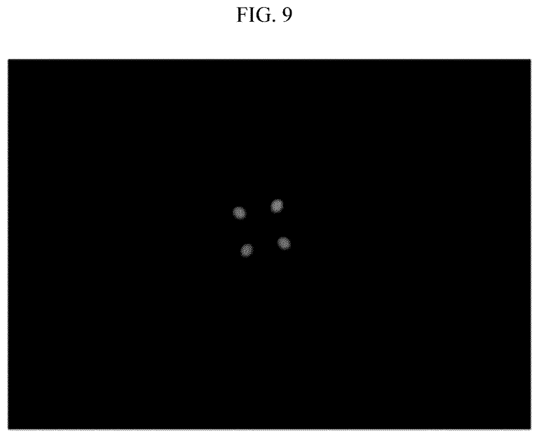

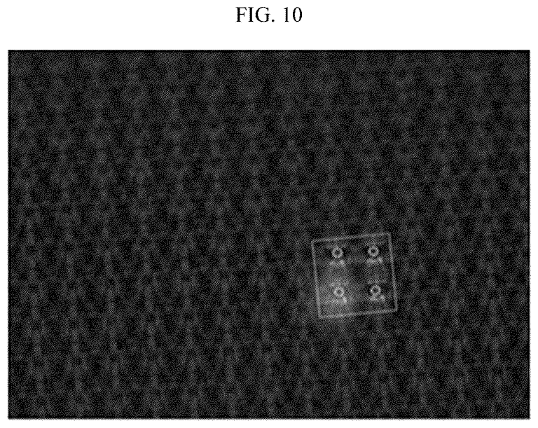

FIG. 6 is a schematic cross-sectional view illustrating an optical path when the light emitting device of the display device according to the embodiment is in an on state. FIG. 7 is a schematic cross-sectional view illustrating an optical path when the light emitting device of the display device according to the embodiment is in an off state. FIG. 8 is a schematic cross-sectional view illustrating an optical path when a light emitting device of a display device according to a reference example is in an off state. FIG. 9 is a view illustrating a front surface of the display device when the light emitting device of the display device according to the reference example is in the off state. FIG. 10 is a view illustrating a rear surface of the display device when the light emitting device of the display device according to the reference example is in the off state.

As shown in FIG. 6, when the light emitting device of the display device according to the embodiment is in the on state, most of light emitted from the light emitting devices ED of each pixel may be emitted to a front surface of the display device (Lout in FIG. 6). A part of the light emitted from the light emitting devices ED may be transmitted to a rear surface of the display device (Lin in FIG. 6). The part of the light transmitted to the rear surface of the display device may be reflected by the opaque conductive material positioned in the wiring area WA to emit to the front surface of the display device or be absorbed inside the display device. At least a portion of the wiring area WA may not have an opaque conductive material which light may pass through. Accordingly, another part of the light transmitted to the rear surface of the display device may pass through the wiring area WA, and may reach the sensor SS through the hole HA of the support member PT. Incident light may be from outside of the display device depending on a use environment of the display device (Lex in FIG. 6). When the user uses the display device in a bright environment, an amount of incident light from the outside may be large, and when the user uses the display device in a dark environment, an amount of the incident light from outside may be small. External light may be partially lost while passing through the light emitting device ED and the wiring area WA, and the remaining light of the external light may pass through the hole HA of the support member PT to be transmitted to the sensor SS.

As shown in FIG. 7, when the light emitting device of the display device according to the embodiment is in the off state, the light emitting devices ED of each pixel do not emit light to the front and rear surfaces of the display device. Incident light may be from outside of the display device regardless of whether the light emitting device ED emits light (Lex in FIG. 7). External light may be partially lost while passing through the light emitting device ED and the wiring area WA, and the remaining light of the external light may pass through the hole HA of the support member PT to be transmitted to the sensor SS.

In the display device according to the embodiment, an on state and an off state of the light emitting device ED may be repeated. When the light emitting device ED is in the on state, the light emitted from the light emitting devices ED and the external light may both be received by the sensor SS. The sensor SS may not distinguish between the light emitted from the light emitting devices ED and the external light, and the sensor SS may not accurately determine an amount of the external light. When the light emitting device ED is in the off state, light may not be emitted from the light emitting devices ED so that only the external light is incident on the sensor SS. The sensor SS may sense only the external light, and may accurately determine an amount of the external light. The sensor SS of the display device according to an embodiment may be operated when the light emitting device ED is in the off state, and may not be operated when the light emitting device ED is in the on state. Accordingly, the sensor SS may determine the amount of the external light without being affected by light emitted from the light emitting device ED.

As shown in FIG. 8, when the light emitting device of the display device according to the reference example is in the off state, residual light due to a leakage current may be generated (Lleak in FIG. 8). Although an interval in which the light emitting device is in the off state is an interval in which no current is applied to the light emitting device ED and light emission does not have to be performed, light emission may be performed. The intermediate layer of the light emitting device ED includes the light emitting layer and a functional layer, and the functional layer may be formed to be entirely connected. When the light emitting device ED is in the on state, an electric field may be formed in the intermediate layer of the light emitting device ED in a vertical direction. When the light emitting device ED is changed to the off state, an electric field in a vertical direction is not formed, and light may be generated while the leakage current moves along the functional layers connected to each other in a horizontal direction. Accordingly, light may be emitted toward the front and rear surfaces of the display device around the partition wall separating the light emitting devices ED of adjacent pixels. As shown in FIG. 9, although the light emitting device of the display device is in the off state, it may be seen that light is emitted to the front surface of the display device. As shown in FIG. 10, it may be seen that light is emitted to the rear surface of the display device even though the light emitting device of the display device is in the off state. The display device may include the red pixel, the green pixel, and the blue pixel, and residual light of the green pixel may be viewed.

When the light emitting device of the display device is in the off state, some of the light emitted to the rear surface of the display device by the leakage current may pass through the wiring area WA, may pass through the hole HA of the support member PT, and may reach the sensor SS. As described above, the sensor SS may be operated when the light emitting device is in the off state, and the residual light when the light emitting device is in the off state may adversely affect a sensing capability of the sensor SS. For example, it may be erroneously determined that the amount of the external light is greater than an actual amount due to the residual light. As a result, brightness of a surrounding environment in which the user uses the display device may be incorrectly detected, and thus, luminance control of the display device may not be properly performed.

In order to prevent the residual light from being generated, a method of lowering conductivity of the hole transport layer and accumulating a hole on a side surface of the electron blocking layer and a side surface of the light emitting layer may be considered. However, resistance in a vertical direction may be increased, and as an electric field is greatly applied to the hole injection layer, the leakage current moves in a horizontal direction. As a result, the residual light may be generated. In the display device according to the embodiment, by appropriately selecting materials of the hole transport layer and the electron blocking layer, mobility of the hole transport layer may be equal to or less than about 2.0*10⁻³ cm²/(Vs), a difference between a HOMO energy level of the hole transport layer and a HOMO energy level of the electron blocking layer may be equal to or less than about 0.1 eV, and a real part of impedance of the light emitting device ED may be equal to or less than about 100Ω in a frequency range of about 10⁵ Hz to about 10⁶ Hz. In the display device according to the embodiment, resistance between the hole transport layer and the electron blocking layer may be reduced to prevent the residual light from being generated while the leakage current moves in the horizontal direction.

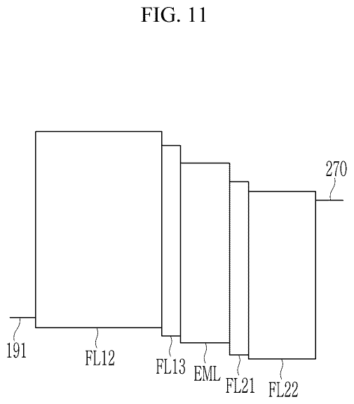

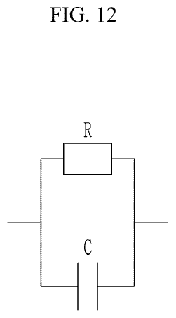

Hereinafter, the real part of the impedance of the light emitting device ED will be described with reference to FIGS. 11 and 12.

FIG. 11 is a schematic view illustrating an energy level diagram of the light emitting device of the display device. FIG. 12 is a schematic diagram of an equivalent circuit of the light emitting device of the display device.

As shown in FIG. 11, the light emitting device of the display device includes the first electrode 191, the second electrode 270, and the light emitting layer EML positioned between the first electrode 191 and the second electrode 270. The hole transport layer FL12 and the electron blocking layer FL13 may be positioned between the first electrode 191 and the light emitting layer EML, and the hole blocking layer FL21 and the electron transport layer FL22 may be positioned between the light emitting layer EML and the second electrode 270. When an electric field is applied to the light emitting device, a hole may be injected in the first electrode 191 and an electron may be injected in the second electrode 270 so that the hole and the electron meet in the light emitting layer EML. A combination of the electron and the hole is called an exciton, and an excited state means a state in which the electron absorbs energy so that a state of the exciton may be more excited than an existing state. The excited state may be a temporarily unstable state, and the electron tries to return to a ground state that is a stable state. As the electron returns from the excited state to the ground state, an energy level of the electron may be lowered back to an original energy level of the electron. The reduced energy may be emitted in a form of light so that the light is recognized.

As shown in FIG. 12, the light emitting device may be represented by an RC equivalent circuit. That is, the light emitting device may be represented as an equivalent circuit in which one resistor R and one capacitor C are connected in parallel. The impedance (Z) in the equivalent circuit of the light emitting device may be expressed as Equation 1, the real part (Re[Z]) of the impedance (Z) may be expressed as Equation 2, and an imaginary part (Im[Z]) of the impedance (Z) may be expressed as Equation 3. A modulus (M) in the equivalent circuit of the light emitting device may be expressed as Equation 4, a real part (Re[M]) of the modulus (M) may be expressed as Equation 5, and an imaginary part (Im[M]) of the modulus (M) may be expressed as Equation 6.

$$Z = \frac{R}{1 + {ω}^{2} {R}^{2} {C}^{2}} + i \frac{ω {R}^{2} C}{1 + {ω}^{2} {R}^{2} {C}^{2}} \qquad [ Equation 1 ]$$

$$Re [ Z ] = \vert Z \vert \sqrt{1 - {ω}^{2} {\vert Z \vert}^{2} {C}^{2}} \qquad [ Equation 2 ]$$

$$Im [ Z ] = ω {\vert Z \vert}^{2} C \qquad [ Equation 3 ]$$

$$M = \frac{{ω}^{2} {R}^{2} C}{1 + {ω}^{2} {R}^{2} {C}^{2}} + i \frac{ω R}{1 + {ω}^{2} {R}^{2} {C}^{2}} \qquad [ Equation 4 ]$$

$$Re [ M ] = {ω}^{2} {\vert Z \vert}^{2} C \qquad [ Equation 5 ]$$

$$Im [ Z ] = ω \vert Z \vert \sqrt{1 - {ω}^{2} {\vert Z \vert}^{2} {C}^{2}} \qquad [ Equation 6 ]$$

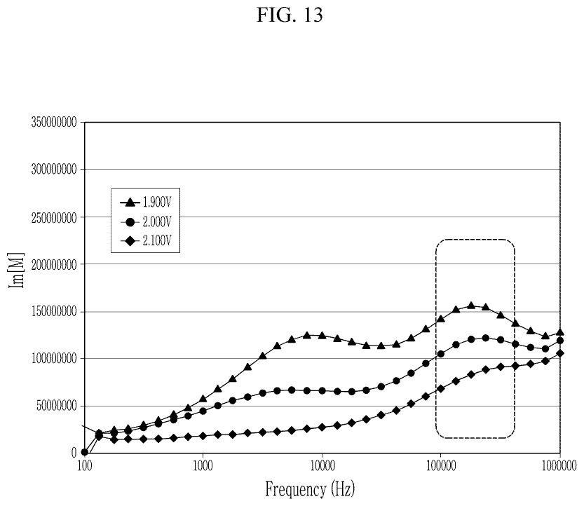

Hereinafter, the display device according to the embodiment and a display device according to various reference examples will be compared and described with reference to Table 1 and FIGS. 13 through 20.

Table 1 shows a HOMO energy level and mobility according to a selected material of the hole transport layer, a HOMO energy level and mobility according to a selected material of the electron blocking layer, a difference (ΔHOMO) between the HOMO energy level of the hole transport layer and the HOMO energy level of the electron blocking layer, and the real part of the impedance of the light emitting device. In Table 1, various cases are shown from Nos. 1 through 9 according to the selected material of the hole transport layer and the selected material of the electronic blocking layer, where No. 7 and No. 9 represent the display device according to the embodiment, and the rest represent the display device according to the reference example.

In Table 1, the HOMO energy level indicates a value measured using cyclic voltammetry (CV). The cyclic voltammetry is an experimental method of obtaining a cyclic voltammogram by measuring a current while scanning an electrical potential at a constant speed with respect to a reference electrode to a working electrode in which a reaction of interest occurs. After dissolving a material of the hole transport layer or a material of the electron blocking layer in an organic solvent such as MC, THF, or the like, the cyclic voltammetry measures the current while scanning from 0 V to 2 V. After ferrocene is dissolved in the same solvent as the above solvent, a current is measured in the same method as the above method so that the measured current is used as a reference value. The HOMO energy level may be derived by comparing the reference value with the previously measured current. Various equipment may be used to measure the current and the like, and values in Table 1 were measured using a facility that is ZIVELAB.

In Table 1, the real part of the impedance of the light emitting device represents a real part of impedance in a frequency range of about 10⁵ Hz to about 10⁶ Hz.

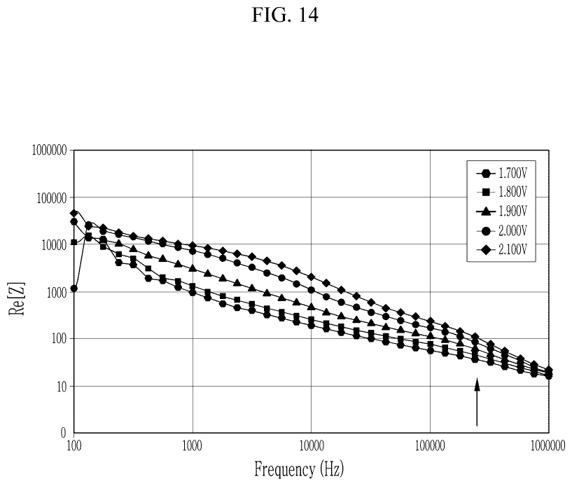

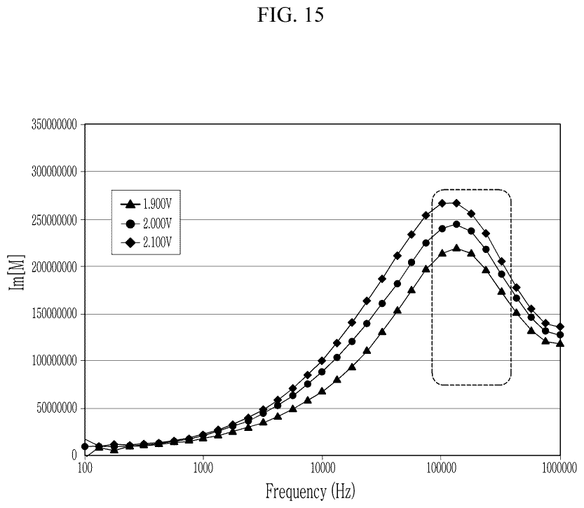

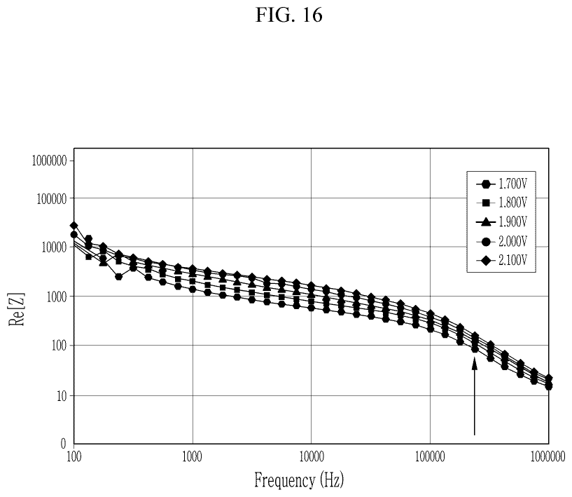

FIG. 13 is a graph illustrating an imaginary part of a modulus of the light emitting device of the display device according to the reference example. FIG. 14 is a graph illustrating a real part of impedance of the light emitting device of the display device according to the reference example. FIGS. 13 and 14 represent a case of Number 1 in Table 1. FIGS. 13 and 14 represent a case in which the hole transport layer includes a compound represented by Chemical Formula 5 and the electron blocking layer includes a compound represented by Chemical Formula 6. FIG. 15 is a graph illustrating an imaginary part of a modulus of the light emitting device of the display device according to the reference example. FIG. 16 is a graph illustrating a real part of impedance of the light emitting device of the display device according to the reference example. FIG. 15 and FIG. 16 represent Number 5 in Table 1. FIG. 15 and FIG. 16 represent a case in which the hole transport layer includes a compound represented by Chemical Formula 1 and the electron blocking layer includes a compound represented by Chemical Formula 6.

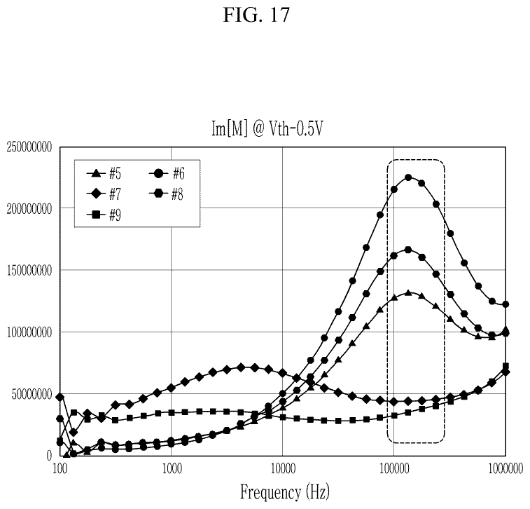

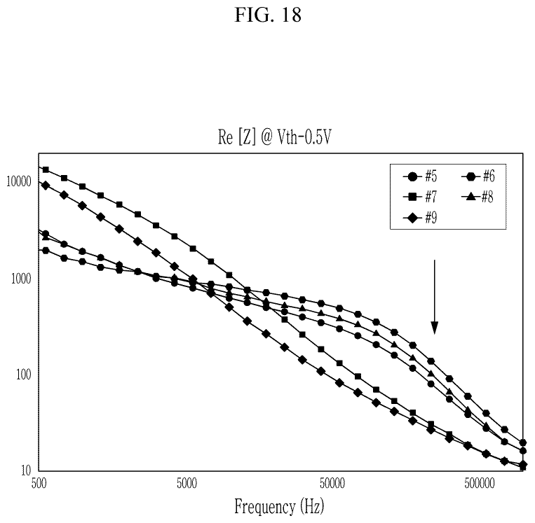

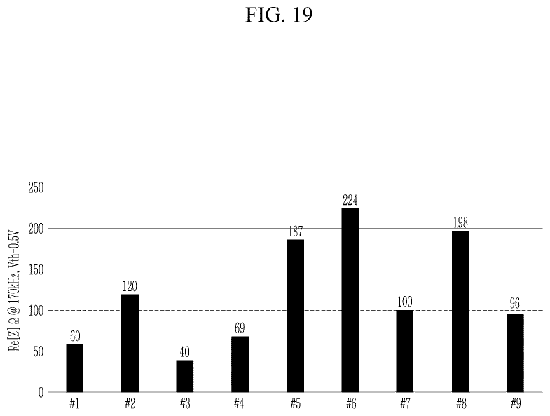

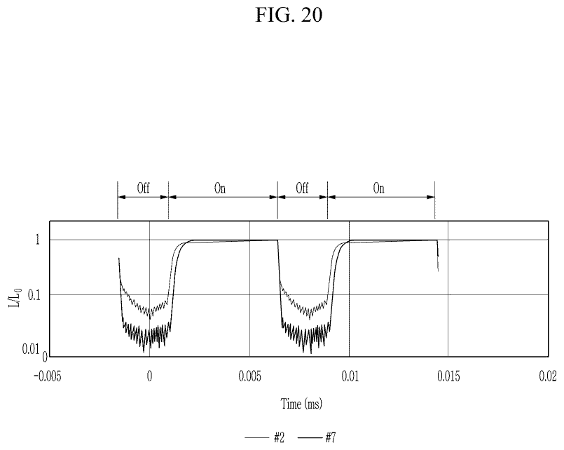

FIG. 17 is a graph illustrating an imaginary part of a modulus of the display device according to the reference example or the light emitting device of the display device according to the embodiment. FIG. 18 is a graph illustrating a real part of impedance of the display device according to the reference example or the light emitting device according to the embodiment. FIGS. 17 and 18 represent Number 5 through Number 9 in Table 1. FIG. 19 is a graph illustrating a real part of impedance of a display device according to the reference example and the light emitting device according to the embodiment. FIG. 19 illustrates the real part of the impedance in a frequency range of about 10⁵ Hz to about 10⁶ Hz. FIG. 20 is a graph illustrating a ratio of amounts of light emitted from a rear surface of the display device according to the reference example and a ratio of amounts of light emitted from a rear surface of the display device according to the embodiment. FIG. 20 represents Number 2 and Number 7 in Table 1.

TABLE 1

| | | | | Electron blocking layer | | | | | |
|---|---|---|---|---|---|---|---|---|---|
| | Hole transport layer | | | | | Dipole | | | Impedance |
| | | HOMO | Mobility | | HOMO | moment | Mobility | ΔHOMO | real part |
| No. | Material | (eV) | (cm²/(Vs)) | Material | (eV) | (C · m) | (cm²/(Vs)) | (eV) | (Ω) |
| 1 | Chemical | −5.13 | 5.0*10⁻³ | Chemical Formula 6 | −5.22 | 0.98 | 1.42*10⁻⁴ | 0.09 | 60 |
| 2 | Formula 5 | | | Chemical Formula 7 | −5.07 | 0.94 | 1.78*10⁻⁴ | 0.06 | 120 |
| 3 | | | | HT20 | −5.12 | 1.46 | 1.20*10⁻⁴ | 0.01 | 40 |
| 4 | | | | Chemical Formula 8 | −5.22 | 0.79 | 2.02*10⁻⁴ | 0.09 | 69 |
| 5 | HT6 | −5.14 | 1.40*10⁻³ | Chemical Formula 6 | −5.22 | 0.98 | 1.42*10⁻⁴ | 0.08 | 187 |
| 6 | | | | Chemical Formula 7 | −5.07 | 0.94 | 1.78*10⁻⁴ | 0.07 | 224 |
| 7 | | | | HT20 | −5.12 | 1.46 | 1.20*10⁻⁴ | 0.02 | 100 |
| 8 | | | | Chemical Formula 8 | −5.22 | 0.79 | 2.02*10⁻⁴ | 0.08 | 198 |
| 9 | | | | HT21 | −5.17 | 0.27 | 1.42*10⁻⁴ | 0.03 | 96 |

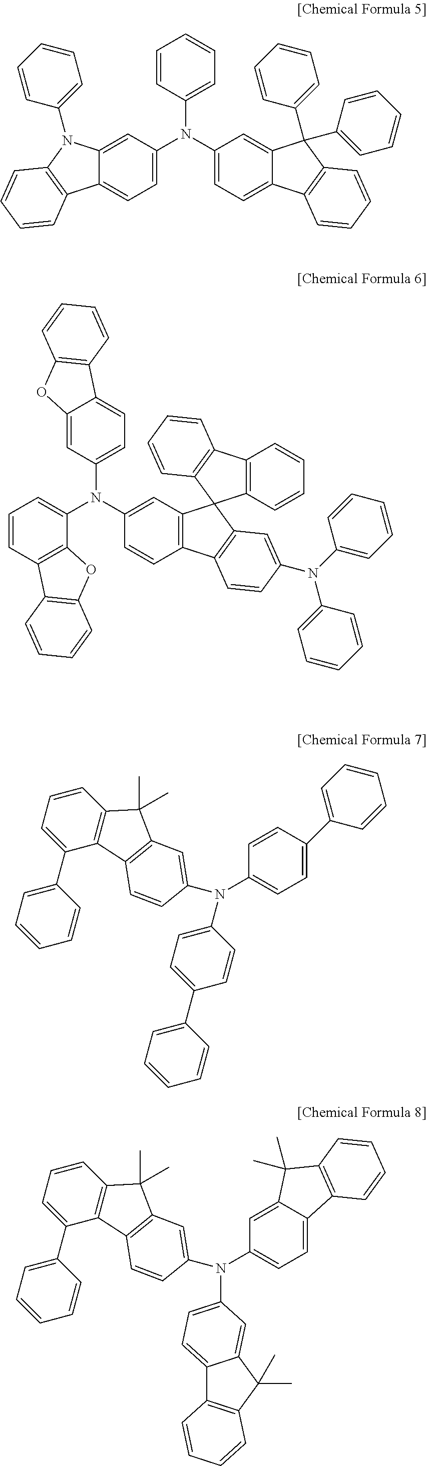 [SMILES: c1ccc(N(c2ccc3c(c2)C(c2ccccc2)(c2ccccc2)c2ccccc2-3)c2ccc3c4ccccc4n(-c4ccccc4)c3c2)cc1 ; c1ccc(N(c2ccccc2)c2ccc3c(c2)C2(c4ccccc4-c4ccccc42)c2cc(N(c4ccc5c(c4)oc4ccccc45)c4cccc5c4oc4ccccc45)ccc2-3)cc1 ; CC1(C)c2cc(N(c3ccc(-c4ccccc4)cc3)c3ccc(-c4ccccc4)cc3)ccc2-c2c(-c3ccccc3)cccc21 ; CC1(C)c2ccccc2-c2ccc(N(c3ccc4c(c3)C(C)(C)c3ccccc3-4)c3ccc4c(c3)C(C)(C)c3cccc(-c5ccccc5)c3-4)cc21]

Referring to FIGS. 13 to 16, it may be seen that when a compound of the hole transport layer is changed from a compound represented by Chemical Formula 1 to a compound represented by Chemical Formula 5 in a state in which a compound of the electron blocking layer is selected as a compound represented by Chemical Formula 6, the imaginary part of the modulus of the light emitting device is greatly increased and the real part of the impedance of the light emitting device is increased in a frequency range of about 10⁵ Hz to about 10⁶ Hz. In the frequency range of about 10⁵ Hz to about 10⁶ Hz, the imaginary part of the modulus of the light emitting device increases from about 1.0*10⁸ to about 2.5*10⁸. In the frequency range of about 10⁵ Hz to about 10⁶ Hz, the real part of the impedance of the light emitting device may increase from equal to or less than about 100Ω to equal to or greater than about 100Ω.

Mobility of the compound represented by Chemical Formula 5 is 5.0*10⁻³ cm²/(Vs), and mobility of the compound represented by Chemical Formula 1 is 1.4*10⁻³ cm²/(Vs). That is, it is possible to increase resistance in a vertical direction by reducing mobility of the hole transport layer. When the mobility of the hole transport layer is reduced as described above, a large electric field may be applied to the hole injection layer so that a leakage current moves in a horizontal direction. As a result, residual light may be generated. In the display device according to an embodiment, the resistance may be lowered by appropriately selecting a material of the electronic blocking layer while maintaining the mobility of the hole transport layer at less than or equal to about 2.0*10⁻³ cm²/(Vs).

Referring to FIGS. 17 through 19, in a state in which the hole transport layer is selected as HT6 among the compound represented by Chemical Formula 1, the imaginary part of the modulus and the real part of the impedance of the light emitting device that correspond to when each of compounds represented by Chemical Formula 6, Chemical Formula 7, HT20, Chemical Formula 8, and HT21 is selected as the electron blocking layer may be checked. It may be seen that when the compound represented by Chemical Formula 6 is selected as the electron blocking layer (#5), a compound represented by Chemical Formula 7 is selected as the electron blocking layer (#6), and a compound represented by Chemical Formula 8 is selected as the electron blocking layer (#8), the imaginary part of the modulus of the light emitting device is equal to or greater than about 1.0*10⁸ in the frequency range of about 10⁵ Hz to about 10⁶ Hz or less. It may be seen that when a compound represented by HT20 is selected as the electron blocking layer (#7) and a compound represented by HT21 is selected as the electron blocking layer (#9), the imaginary part of the modulus of the light emitting device is lowered to equal to or less than about 0.5*10⁸ in the frequency range of about 10⁵ Hz to about 10⁶ Hz. It may be seen that when the compound represented by Chemical Formula 6 is selected as the electron blocking layer (#5), the compound represented by Chemical Formula 7 is selected as the electron blocking layer (#6), and the compound represented by Chemical Formula 8 is selected as the electron blocking layer (#8), the real part of the impedance of the light emitting device is equal to or greater than about 100Ω in the frequency range of about 10⁵ Hz to about 10⁶ Hz. It may be seen that when the compound represented by HT20 is selected as the electron blocking layer (#7) and the compound represented by HT21 is selected as the electron blocking layer (#9), the real part of the impedance of the light emitting device is equal to or less than about 100Ω in the frequency range of about 10⁵ Hz to about 10⁶ Hz.

In the display device according to an embodiment, materials of the hole transport layer and the electron blocking layer may be selected so that the mobility of the hole transport layer is equal to or less than about 2.0*10⁻³ cm²/(Vs), a difference between a HOMO energy level of the hole transport layer and a HOMO energy level of the electron blocking layer may be equal to or less than about 0.1 eV, and the real part of the impedance of the light emitting device may be equal to or less than about 100Ω in a frequency range of about 10⁵ Hz to about 10⁶ Hz. Accordingly, it is possible to prevent the residual light from being generated due to a movement of the leakage current when the light emitting device of the display device is in the off state, and it is possible to prevent a malfunction of the sensor due to the residual light in the off state.

As shown in FIG. 20, a ratio (or a light intensity ratio) (L/L₀) of amounts of light emitted to a rear surface of the display device may be changed according to an on/off state of the light emitting device. When the light emitting device is in the on state, a maximum light intensity ratio (L/L₀) may be about 1, and when the light emitting device is in the off state, the light intensity ratio (L/L₀) may be in a range of about 0.1 to about 0.01. It may be seen that as the light quantity ratio (L/L₀) that corresponds to when the light emitting device is in the off state has a value close to 0, the residual light due to the leakage current is small. It may be seen that the light quantity ratio (L/L₀) that corresponds to when the light emitting device is in the off state in a case in which the hole transport layer is selected as the compound represented by Chemical Formula 1 and the electron blocking layer is selected as the compound represented by HT20 (#7) has a value closer to 0 than the light quantity ratio (L/L₀) that corresponds to when the light emitting device is in the off state in a case in which the hole transport layer is selected as the compound represented by Chemical Formula 5 and the electron blocking layer is represented by Chemical Formula 7 (#2). In the display device according to the embodiment, it is possible to prevent the residual light due to the leakage current from being generated when the light emitting device is in the off state.

As described above, in the display device according to the embodiment, a characteristic of the light emitting device may be controlled by selecting materials of the hole transport layer and the electron blocking layer. It is common that the functional layer such as the hole transport layer or the electron blocking layer may be entirely formed at the display area of the display device. For example, a common hole transport layer and a common electron blocking layer may be formed at the sensor area or at the display area excluding the sensor area. However, the display device according to the embodiment is not limited thereto, and a material of the hole transport layer positioned in the sensor area may be different from a material of the hole transport layer positioned in the display region excluding the sensor area. Hole transport layers made of different materials may be formed in the sensor area and the display area excluding the sensor area using different masks. Similarly, a material of the electron blocking layer positioned in the sensor area may be different from a material of the electron blocking layer position in the display area excluding the sensor area. Electron blocking layers made of different materials may be formed in the sensor area and the display area except for the sensor area using different masks. In the sensor area, mobility of the hole transport layer may be equal to or less than about 2.0*10⁻³ cm²/(Vs), a difference between a HOMO energy level of the hole transport layer and a HOMO energy level of the electron blocking layer may be equal to or less than about 0.1 eV, and a real part of impedance of the light emitting device may be equal to or less than about 100Ω in a frequency range of about 10⁵ Hz to about 10⁶ Hz or less. In the display area except for the sensor area, the hole transport layer, the electron blocking layer, and the light emitting device may have a characteristic outside of the numerical range.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display device comprising:
a substrate;
a transistor disposed on the substrate; and
a light emitting device that is electrically connected to the transistor, wherein
the light emitting device comprises:
a first electrode that is electrically connected to the transistor;
a second electrode disposed on the first electrode;
a light emitting layer disposed between the first electrode and the second electrode;
a hole transport layer disposed between the first electrode and the light emitting layer; and
an electron blocking layer disposed between the hole transport layer and the light emitting layer,
mobility of the hole transport layer is equal to or less than about 2.0*10⁻³ cm²/(Vs), and
a real part of impedance of the light emitting device is equal to or less than about 100Ω, in a frequency range of about 10⁵ Hz to about 10⁶ Hz.

2. The display device of claim 1, wherein a difference between a highest occupied molecular orbital (HOMO) energy level of the hole transport layer and a HOMO energy level of the electron blocking layer is equal to or less than about 0.1 eV.

3. The display device of claim 1, further comprising:
a sensor disposed at a rear surface of the substrate, wherein
the sensor overlaps the light emitting device.

4. The display device of claim 3, wherein the sensor includes an ambient luminance sensor.

5. The display device of claim 4, wherein
the sensor is operated when the light emitting device in an off state, and
the sensor is not operated when the light emitting device is in an on state.

6. The display device of claim 4, wherein
the sensor detects incident light outside the display device, and
the sensor adjusts a brightness of the display device according to an amount the incident light.

7. The display device of claim 3, further comprising:
a support member disposed between the substrate and the sensor, wherein
the support member includes a hole overlapping the sensor.

8. The display device of claim 3, further comprising:
an auxiliary layer disposed on the light emitting device, wherein
the auxiliary layer includes at least one of a color filter, a quantum dot color conversion layer, a touch sensor, and a polarization layer.

9. The display device of claim 1, wherein the hole transport layer includes a compound represented by Chemical Formula 1: 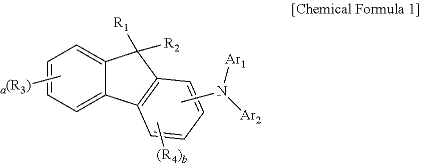
wherein in Chemical Formula 1,
R₁ through R₄ are each independently hydrogen, deuterium, a substituted or unsubstituted C₁-C₃₀ alkyl group, a substituted or unsubstituted C₁-C₃₀ cycloalkyl group, a substituted or unsubstituted C₆-C₃₀ aryl group, or a substituted or unsubstituted C₂-C₃₀ heteroaryl group, or are bonded to an adjacent group to form a ring,
Ar₁ and Ar₂are each independently a substituted or unsubstituted C₆-C₃₀ aryl group or a substituted or unsubstituted C₂-C₃₀ heteroaryl group,
a is an integer from 0 to 4, and
b is an integer from 0 to 3.

10. The display device of claim 9, wherein the electron blocking layer includes the compound represented by Chemical Formula 1.

11. The display device of claim 10, wherein the electron blocking layer includes a material that is different from a material of the hole transport layer.

12. The display device of claim 10, further comprising:
an auxiliary electron blocking layer disposed between the electron blocking layer and the light emitting layer, wherein
the auxiliary electron blocking layer includes a material that is different from the material of the electron blocking layer.

13. The display device of claim 12, wherein the auxiliary electron blocking layer includes the compound represented by Chemical Formula 1.

14. A display device comprising:
a display panel; and
a sensor disposed at a rear surface of the display panel, wherein
the display panel comprises:
a transistor disposed on a substrate; and
a light emitting device that is electrically connected to the transistor, the light emitting device comprises:
a first electrode that is electrically connected to the transistor;
a second electrode disposed on the first electrode;
a light emitting layer disposed between the first electrode and the second electrode;
a hole transport layer disposed between the first electrode and the light emitting layer; and
an electron blocking layer disposed between the hole transport layer and the light emitting layer, and
a real part of impedance of the light emitting device is equal to or less than about 100Ω, in a frequency range of about 10⁵ Hz to about 10⁶ Hz.

15. The display device of claim 14, wherein mobility of the hole transport layer is equal to or less than about 2.0*10⁻³ cm²/(Vs).

16. The display device of claim 15, wherein a difference between a highest occupied molecular orbital (HOMO) energy level of the hole transport layer and a HOMO energy level of the electron blocking layer is equal to or less than about 0.1 eV.

17. The display device of claim 14, wherein
the sensor includes an ambient luminance sensor, and
the sensor overlaps the light emitting device.

18. The display device of claim 17, wherein
the sensor is operated when the light emitting device is in an off state, and
the sensor is not operated when the light emitting device is in an on state.

19. The display device of claim 17, wherein
the sensor detects incident light from outside the display device, and
the sensor adjusts a brightness of the display panel according to an amount of the incident light.

20. A display device comprising:
a display panel including a substrate,
a transistor disposed on the substrate, and
a light emitting device that is electrically connected to the transistor, wherein
the light emitting device comprises:
a first electrode that is electrically connected to the transistor;
a second electrode disposed on the first electrode;
a light emitting layer disposed between the first electrode and the second electrode;
a hole transport layer disposed between the first electrode and the light emitting layer; and
an electron blocking layer disposed between the hole transport layer and the light emitting layer,
the hole transport layer and the electron blocking layer each independently include a compound represented by Chemical Formula 1, and
the compound of the electron blocking layer is different from the compound of the hole transport layer: 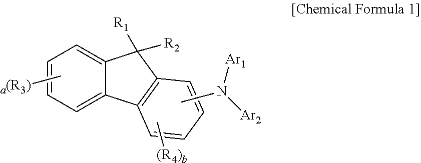
wherein in Chemical Formula 1,
R₁ through R₄ are each independently hydrogen, deuterium, a substituted or unsubstituted C₁-C₃₀ alkyl group, a substituted or unsubstituted C₁-C₃₀ cycloalkyl group, a substituted or unsubstituted C₆-C₃₀ aryl group, or a substituted or unsubstituted C₂-C₃₀ heteroaryl group, or are bonded to an adjacent group to form a ring,
Ar₁ and Ar₂ are each independently a substituted or unsubstituted C₆-C₃₀ aryl group or a substituted or unsubstituted C₂-C₃₀ heteroaryl group,
a is an integer from 0 to 4, and
b is an integer from 0 to 3.
